(19) United States
(12) Patent Application Publication
(10) Pub. No.: US 2011/0286195 A1
(43) Pub. Date: Nov. 24, 2011

(54) ELECTRONIC SHELF LABEL, INFORMATION DISPLAY PANEL, AND INFORMATION DISPLAY METHOD

(76) Inventors: Keiichi Horikiri, Chiba (JP); Hiromi Chida, Chiba (JP)

(21) Appl. No.: 12/998,605

(22) PCT Filed: Oct. 9, 2009
(86) PCT No.: PCT/JP2009/067676

§ 371 Date: May 6, 2011

(30) Foreign Application Priority Data
Nov. 7, 2008 (JP) 2008-286665

(51) Int. Cl. H05K 7/00

(52) U.S. Cl. 361/807

(57) ABSTRACT

Supporting force for an information display panel is increased to reduce troubles such as displacement and removal of the panel, and attachment and detachment of the information display panel are facilitated. An electronic shelf label (1) includes an electronic shelf label body (2) having a liquid crystal panel (21), and a shelf label frame (3) for housing the electronic shelf label body (2). The shelf label frame (3) includes a frame-like portion (32), which is arranged on a display portion surface side and has a window for an electronic display portion formed therein, and a pair of opposing guide rails (33A and 33B), which are provided on a surface of the frame-like portion (32) and are capable of holding a window frame display panel (4) capable of displaying arbitrary information with the window frame display panel (4) inserted thereinto from above the display portion surface.

### TECHNICAL FIELD

The present invention relates to an electronic shelf label, an information display panel, and an information display method, which are used for displaying a product price and the like in a retail store and the like.

### BACKGROUND ART

In recent years, in a retail store such as a supermarket, electronic shelf labels that display product prices have been attached to a product display shelf so that products in the store are controlled centrally. For example, a price of a product that changes on a daily or weekly basis is transmitted as a signal to an electronic shelf label of the target product, and accordingly price display can be changed easily and efficiently. To such an electronic shelf label, a detachable information display panel for displaying characters and numerals is attached particularly for the purpose of attracting customers' attention to products on sale or the like (see, for example, PTL 1).

FIG. 11 illustrates an example of the conventional electronic shelf label described above, and is a perspective view illustrating structure described in PTL 1, for mounting the information display panel on the electronic shelf label. Specifically, in an information display panel 100 illustrated in FIG. 11, a window hole 101 is formed so as to expose a display part of an electronic shelf label 110 for displaying a product price, and an elastically deformable member with a window frame 102 for displaying characters and numerals is formed on the periphery of the window hole 101. The electronic shelf label 110 on which the information display panel 100 is to be mounted has attachment grooves 111, which are formed into a groove shape in the periphery of side surfaces 110a (outer peripheral surfaces of the electronic shelf label 110 defined in its thickness direction) of a frame portion along a circumferential direction, the frame portion forming a contour, for housing an electronic display portion. In the electronic shelf label 110, each of the attachment grooves 111 is formed of protrusions 111a and 111b protruding from the side surface 110a. The window hole 101 is fitted into the attachment grooves 111 while the information display panel 100 is elastically deformed, and as a result, the information display panel 100 is mounted on the side surfaces 110a of the electronic shelf label 110.

### Citation List

### Patent Literature

[PTL 1] JP 2005-40334 A

### SUMMARY OF INVENTION

### Technical Problems

However, the shelf label frame disclosed in PTL 1 has the following problems.

That is, in PTL 1 illustrated in FIG. 11, in order that the shelf label frame 100 be prevented from being removed from the shelf label 110, it is necessary to support the shelf label frame 100 by the attachment grooves 111 and 111 on at least the pair of opposing side surfaces 110a of the shelf label 110. However, there is a problem that it is not easy to fit the window hole 101, while deforming the shelf label frame 100, into the attachment grooves 111 and 111 that are formed in outer peripheral portions of the upper and lower side surfaces of the shelf label 110.

Further, in the attachment structure, inner peripheral portions of the shelf label frame are fitted into the outer peripheral side surfaces of the shelf label. In such structure, the shelf label frame is therefore easily displaced from the attachment grooves of the shelf label, and the shelf label frame is easily displaced and removed because, for example, a customer touches the shelf label frame when picking up a product. Consequently, it takes labor and a period of time to fix the displacement.

The present invention has been made in view of the above-mentioned problems, and it is therefore an object thereof to provide an electronic shelf label, an information display panel, and an information display method, with which supporting force for the information display panel is increased to reduce troubles such as displacement and removal of the panel, and attachment and detachment of the information display panel are facilitated.

### Solution to Problems

In order to achieve the above-mentioned object, the present invention provides an electronic shelf label including: an electronic shelf label body including an electronic display portion; and a shelf label frame for housing the electronic shelf label body, in which the shelf label frame includes: a frame-like portion having a window for the electronic display portion formed therein; and a pair of opposing guide rails, which are arranged on a display portion surface side of the frame-like portion and are capable of holding an information display panel capable of displaying arbitrary information with the information display panel inserted into the pair of opposing guide rails in any one of a longitudinal direction and a lateral direction.

Further, the present invention provides an information display panel, which can be held by the pair of opposing guide rails of the above-mentioned electronic shelf label, so as to be removably attached thereto.

Further, the present invention provides an information display method, in which an electronic shelf label is used, the electronic shelf label including: an electronic shelf label body including an electronic display portion; and a shelf label frame for housing the electronic shelf label body, the information display method including: displaying an arbitrary price on the electronic display portion of the electronic shelf label body; and holding an information display panel with the information display panel inserted into guide rails in any one of a longitudinal direction and a lateral direction, the guide rails being provided on a display portion surface side of a frame-like portion having a window for the electronic display portion formed therein, and displaying arbitrary information on the information display panel.

In the present invention, the information display panel is inserted in the longitudinal direction or the lateral direction along the pair of guide rails provided to the frame-like portion, and hence it is possible to attach and replace the information display panel on the display surface side of the frame-like portion. Accordingly, for example, a product price can be displayed on the electronic display portion of the electronic shelf label body and in addition, the information display panel can perform display with the aid of character information and color-coding. Further, the information display panel is supported by the guide rails and the information display panel is attached on the display surface side, resulting in structure with increased supporting force for the information display panel.

Further, in the electronic shelf label according to the present invention, it is preferred that the information display panel can be inserted into the pair of opposing guide rails from above the display portion surface.

In the present invention, the information display panel can be inserted into the guide rails of the frame-like portion from above, and accordingly, even if the electronic shelf labels are arranged on the product display shelf side by side in a close state, the information display panel can be attached and replaced easily without interfering with the electronic shelf label arranged side by side.

Further, in the electronic shelf label according to the present invention, it is preferred that the pair of opposing guide rails each include a locking portion for regulating movement of the information display panel that is caused by insertion.

In the present invention, when the information display panel is inserted while being moved along the guide rails, the information display panel abuts against the locking portions provided at predetermined positions, and as a result, the information display panel is locked. Accordingly, the information display panel can be held at a predetermined position with respect to the frame-like portion.

Further, the information display panel according to the present invention may be shaped so as to cover and overlap with a frame part of the frame-like portion.

Accordingly, the region of the frame-like portion on the periphery of the electronic display portion serves as an information display portion of the information display panel, on which character information and the like can be displayed. Further, the information display panel does not project outward beyond the shelf label frame, and hence it is possible to eliminate troubles such as displacement that may occur because, for example, a customer touches the information display panel when picking up a product from the product display shelf.

Further, the information display panel according to the present invention may be shaped so that a display part thereof extends in a direction opposite to a direction in which the information display panel is inserted into the pair of opposing guide rails.

In the present invention, the display part is increased in area by an extension amount of the information display panel, and hence it is possible to display more information independently of the electronic display portion of the electronic shelf label body.

Further, the information display panel according to the present invention may include a clear case, into which another display member can be inserted.

In the present invention, under the state in which the clear case is mounted on the shelf label frame, the another display member on which character information and the like are placed as appropriate is inserted into an insertion region of the clear case that is held by the guide rails of the shelf label frame, and hence it is possible to display other information than that of the electronic display portion of the electronic shelf label body.

### Advantageous Effects of Invention

According to the electronic shelf label, the information display panel, and the information display method of the present invention, the information display panel can be mounted on the shelf label frame easily by a simple method in which the information display panel is inserted into the guide rails provided to the display surface side of the frame-like portion. Further, the information display panel is in a state of being held by the guide rails, resulting in the structure with increased supporting force for the information display panel. Accordingly, there are provided advantages of reducing troubles such as displacement and removal of the information display panel that may occur because, for example, a customer touches the information display panel when picking up a product from the product display shelf, and of eliminating the labor and period of time required to cope with such troubles.

### BRIEF DESCRIPTION OF DRAWINGS

FIG. 1 is a perspective view illustrating schematic structure of an electronic shelf label according to a first embodiment of the present invention.

FIG. 2 is a front view of the electronic shelf label.

FIG. 3 is a side view of the electronic shelf label taken along the arrow A-A of FIG. 2.

FIG. 4 is a bottom view of the electronic shelf label taken along the arrow B-B of FIG. 2.

FIG. 5 is a sectional view taken along the arrow C-C of FIG. 2.

FIG. 6 is an enlarged view of an end portion of the electronic shelf label illustrated in FIG. 5.

FIG. 7 is a front view illustrating structure of an electronic shelf label according to a second embodiment.

FIG. 8 are views illustrating structure of an electronic shelf label according to a third embodiment, in which FIG. 8(a) is a front view thereof and FIG. 8(b) is a side view thereof.

FIG. 9 is a perspective view illustrating structure of an electronic shelf label according to a fourth embodiment, and illustrates a state in which the electronic shelf label is attached to a holder.

FIG. 10 is a side view of the electronic shelf label illustrated in FIG. 9.

FIG. 11 is a perspective view illustrating an example of a conventional electronic shelf label.

### DESCRIPTION OF EMBODIMENTS

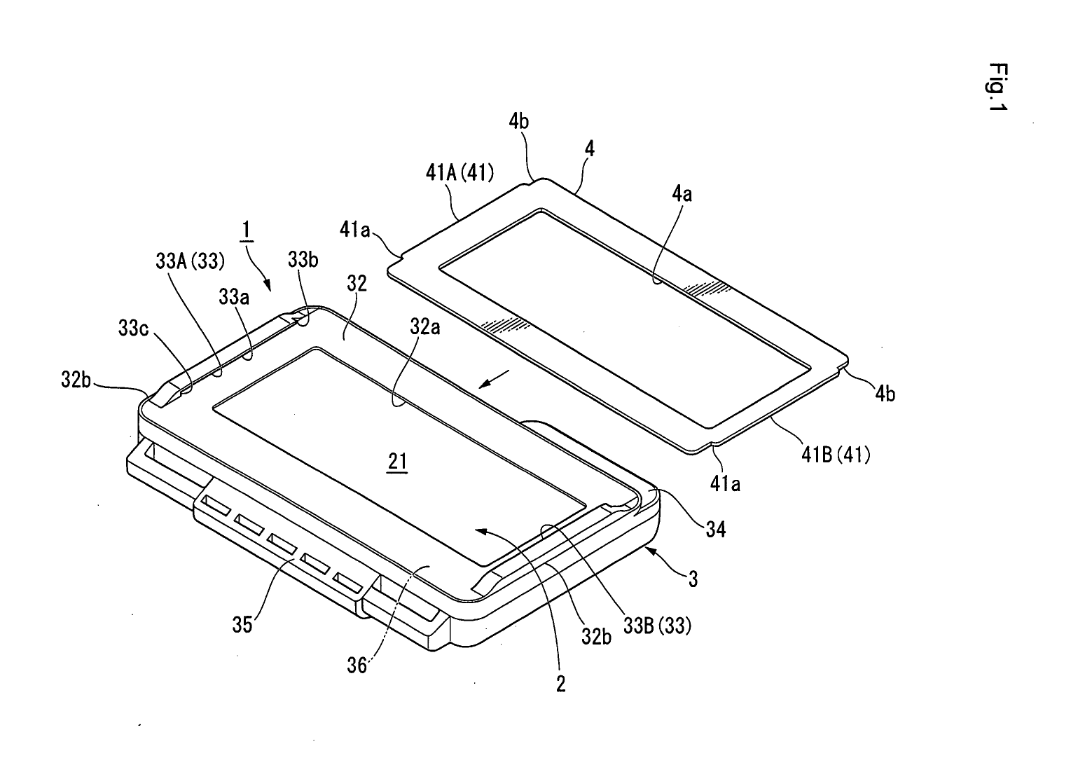

Hereinbelow, referring to FIGS. 1 to 6, description is given of an electronic shelf label, an information display panel, and an information display method according to a first embodiment of the present invention.

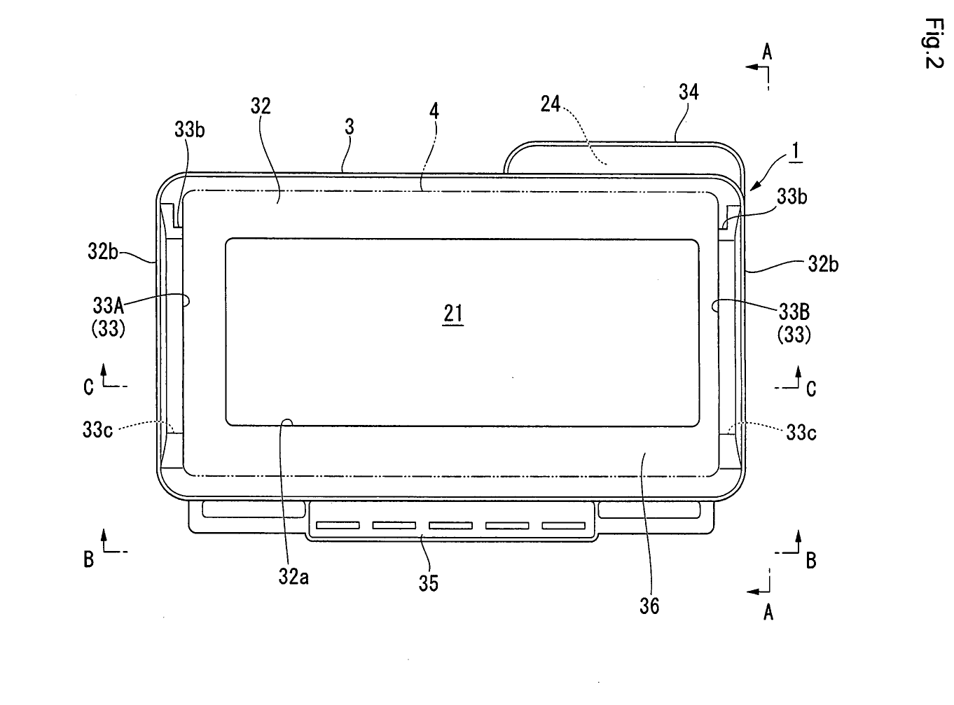

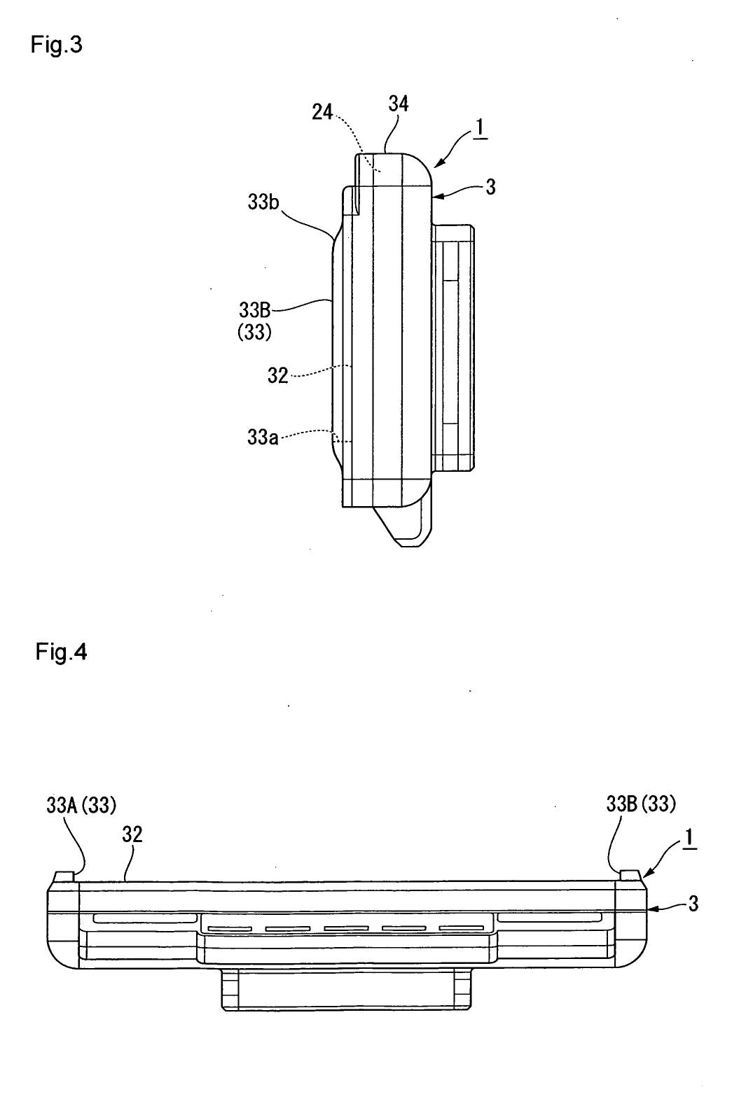

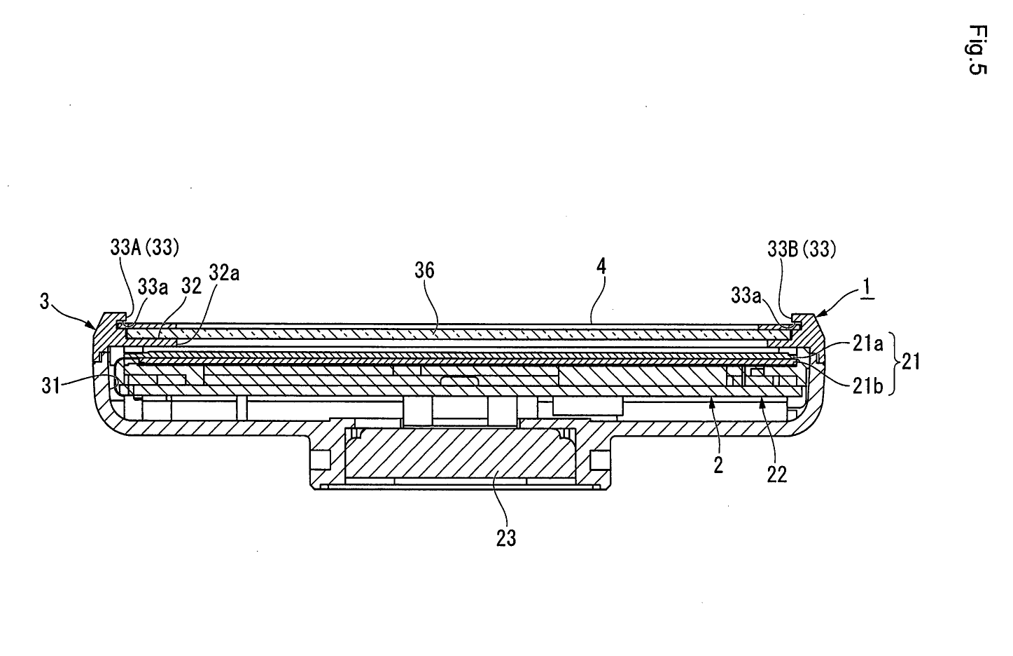

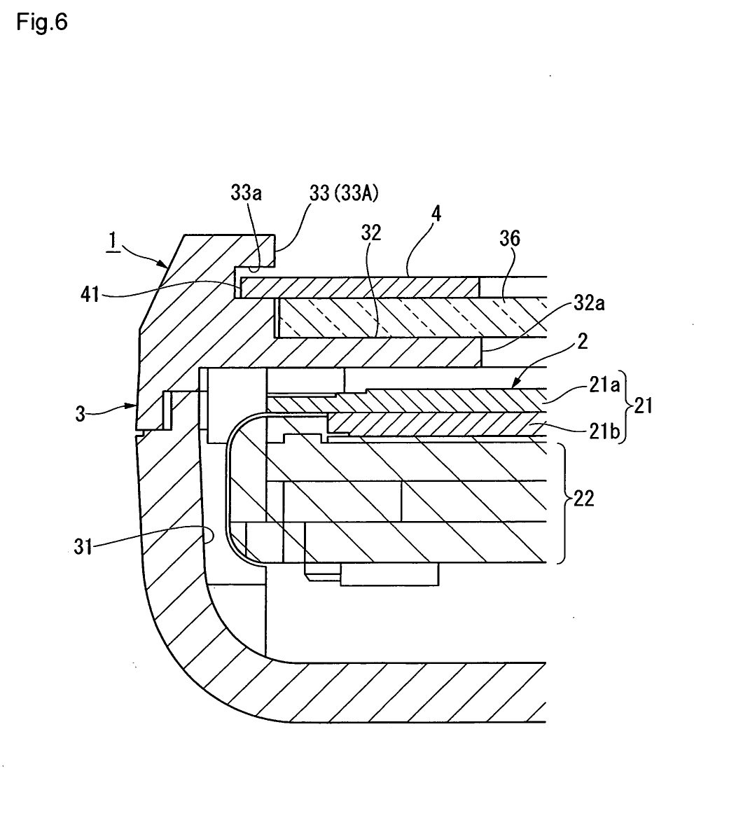

FIG. 1 is a perspective view illustrating schematic structure of the electronic shelf label according to the first embodiment of the present invention. FIG. 2 is a front view of the electronic shelf label. FIG. 3 is a side view of the electronic shelf label taken along the arrow A-A of FIG. 2. FIG. 4 is a bottom view of the electronic shelf label taken along the arrow B-B of FIG. 2. FIG. 5 is a sectional view taken along the arrow C-C of FIG. 2. FIG. 6 is an enlarged view of an end portion of the electronic shelf label illustrated in FIG. 5.

As illustrated in FIG. 1, an electronic shelf label 1 according to the first embodiment is used at, for example, a product shelf in a retail store such as a supermarket to display a product price in an electronic manner. The electronic shelf label 1 has a function of differentiating, for example, a product on sale with the aid of character information and color-coding as well as displaying a price, to thereby attract customers' attention. FIG. 1 illustrates a state in which a window frame display panel 4 described later is not mounted on but separated from a shelf label frame 3.

As illustrated in FIGS. 1 to 4, the electronic shelf label 1 includes an electronic shelf label body 2 having a liquid crystal panel 21 (electronic display portion) for displaying, for example, a product price, and the shelf label frame 3 for housing the electronic shelf label body 2 thereinside. On a display surface side of the shelf label frame 3, the window frame display panel (information display panel) capable of displaying arbitrary information (for example, character information and color) can be attached and detached.

In FIG. 2, the window frame display panel 4 is indicated by a two-dot chain line, and in FIGS. 3 and 4, the window frame display panel 4 is omitted. Further, in the following description, the term “above” regarding the electronic shelf label 1 refers to a position on an upper side of FIG. 2, while the term “below” refers to a position on a lower side thereof.

As illustrated in FIGS. 5 and 6, the electronic shelf label body 2 schematically includes the two upper and lower liquid crystal panels 21 (21a and 21b), a main substrate 22 provided on a back surface side (in FIGS. 5 and 6, lower side) of the lower liquid crystal panel 21b, a battery 23 provided on a back surface side of the main substrate 22, and an antenna 24 (see FIG. 2) attached to an upper portion of the main substrate 22, for receiving, at a terminal (not shown), information to be displayed on the liquid crystal panel 21. For example, memory liquid crystal, which utilizes no electricity, is employed for the electronic shelf label body 2.

As illustrated in FIGS. 2 to 6, the shelf label frame 3 has a function of a cover for housing the electronic shelf label body 2 as described above. The shelf label frame 3 schematically includes a housing portion 31 (see FIGS. 5 and 6), a frame-like portion 32 having an opening window 32a (window) formed therein, the opening window 32a being provided for exposing, on the display surface side, the liquid crystal panel 21 of the electronic shelf label body 2, and a pair of opposing guide rails 33 (33A and 33B), which are provided on a surface of the frame-like portion 32 and are capable of holding the window frame display panel 4 with the window frame display panel 4 inserted thereinto in a longitudinal direction. Further, the shelf label frame 3 includes, in an upper portion thereof, an antenna housing portion 34 for housing the antenna 24 of the electronic shelf label body 2, and in a lower portion thereof, a barcode attachment portion 35.

As described above, the frame-like portion 32 has the substantially rectangular opening window 32a formed therein, and the opening window 32a has an appropriate size so that a display portion of the liquid crystal panel 21 may be exposed in FIG. 2. In this embodiment, a transparent acrylic plate 36 is further provided over substantially the entire display portion surface side of the frame-like portion 32.

The guide rails 33A and 33B are arranged on the display surface side of the display portion of the frame-like portion 32, and are arranged so as to extend in the longitudinal direction along both edge portions 32b and 32b (see FIG. 2), which are located on both right and left sides of the frame-like portion 32. Each of the guide rails 33A and 33B has a recessed groove 33a formed therein, the recessed groove 33a opening inward (on the opening window 32a side) in sectional view as illustrated in FIGS. 5 and 6. Each of the guide rails 33A and 33B has an insertion portion 33b formed therein, the insertion portion 33b opening in its upper end, and also has a locking portion 33c provided thereto in its lower end, the locking portion 33c regulating movement of the window frame display panel 4 that is caused by insertion (see FIG. 1).

In other words, the respective recessed grooves 33a of the guide rails 33A and 33B have a function of guiding right and left end portions (holding end portions 41 described later) of the window frame display panel 4 inserted via the insertion portions 33b, and holding the window frame display panel 4 thus inserted.

As illustrated in FIG. 1, the window frame display panel 4 is shaped so as to cover and overlap with a frame part of the frame-like portion 32, that is, shaped into a frame with an opening portion 4a formed therein, to thereby have substantially the same shape as the frame-like portion 32. The surface of the window frame display panel 4 may be, for example, color-coded, and character information (for example, name of a supermarket) may be placed thereon. Under the state in which the window frame display panel 4 is mounted on the shelf label frame 3, a display region of the liquid crystal panel 21 of the electronic shelf label body 2 is put within the opening portion 4a of the window frame display panel 4. In other words, the region of the frame-like portion 32 on the periphery of the liquid crystal panel 21 serves as an information display portion of the window frame display panel 4, on which character information and the like can be displayed.

The protruding end portions 41 (41A and 41B), which project laterally, are formed in both side edge portions 4b and 4b of the window frame display panel 4. The protruding portions 41A and 41B formed on both the right and left sides are guided downward along the recessed grooves 33a of the guide rails 33A and 33B corresponding to the protruding portions 41A and 41B, respectively, and bottom surface portions 41a of the protruding portions 41 abut against the locking portions 33c of the guide rails 33, with the result that the protruding portions 41A and 41B are locked.

Next, referring to the drawings, detailed description is given of effects of the electronic shelf label 1 thus structured.

As illustrated in FIG. 1, the window frame display panel 4 is inserted downward via the insertion portions 33b along the pair of guide rails 33A and 33B provided to the frame-like portion 32, and hence it is possible to attach and replace the window frame display panel 4 on the display surface side of the frame-like portion 32. Accordingly, for example, a product price can be displayed on the liquid crystal panel 21 of the electronic shelf label body 2 and in addition, the window frame display panel 4 can perform display with the aid of character information and color-coding.

Further, the window frame display panel 4 can be inserted into the guide rails 33A and 33B from above, and accordingly, even if the electronic shelf labels 1 are arranged on the product display shelf side by side in a close state, the window frame display panel 4 can be attached and replaced easily without interfering with the electronic shelf label 1 arranged side by side. Moreover, the window frame display panel 4 mounted on the shelf label frame 3 does not project outward beyond the shelf label frame 3, and hence it is possible to eliminate troubles such as displacement that may occur because, for example, a customer touches the window frame display panel 4 when picking up a product from the product display shelf.

Further, the window frame display panel 4 is supported by the recessed grooves 33a of the guide rails 33A and 33B and the window frame display panel 4 is attached on the display surface side, resulting in structure with increased supporting force for the window frame display panel 4.

Further, when the window frame display panel 4 is inserted while being moved along the guide rails 33A and 33B, the bottom surface portions 41a of the protruding portions 41 of the window frame display panel 4 abut against the locking portions 33b provided at predetermined positions, and as a result, the protruding portions 41A and 41B are locked. Accordingly, the window frame display panel 4 can be held at a predetermined position with respect to the frame-like portion 32 (liquid crystal panel 21).

As described above, according to the electronic shelf label, the information display panel, and the information display method of the first embodiment, the window frame display panel 4 can be mounted on the shelf label frame 3 easily by the simple method in which the window frame display panel 4 is inserted into the guide rails 33A and 33B provided on the display surface side of the frame-like portion 32. Further, the window frame display panel 4 is in a state of being held by the guide rails 33A and 33B, resulting in the structure with increased supporting force for the window frame display panel 4. Accordingly, there are provided advantages of reducing troubles such as displacement and removal of the window frame display panel 4 that may occur because, for example, a customer touches the window frame display panel 4 when picking up a product from the product display shelf, and of eliminating the labor and period of time required to cope with such troubles.

Next, referring to the drawings, description is given of other embodiments, but members or parts identical or similar to those in the above-mentioned first embodiment are denoted by the same reference symbols to omit their description, and the description is given only of structure different from that of the first embodiment.

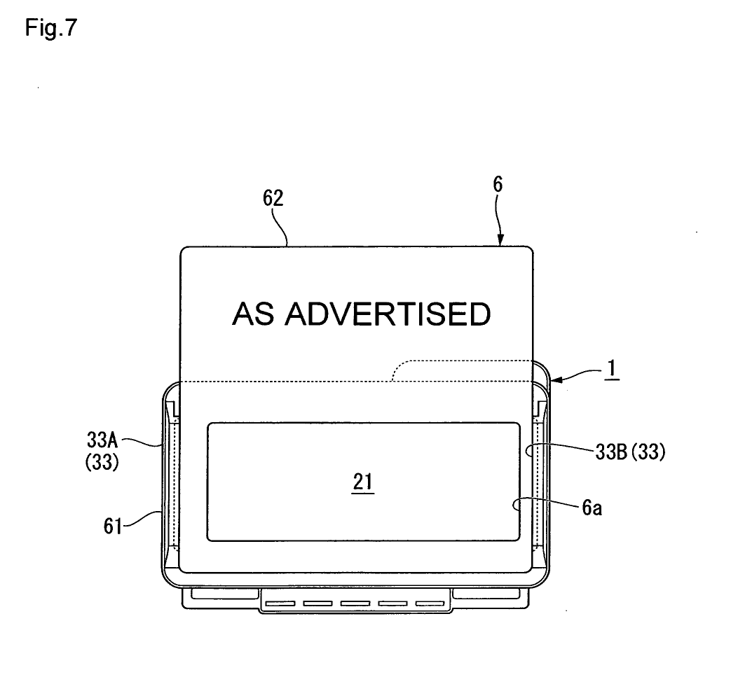

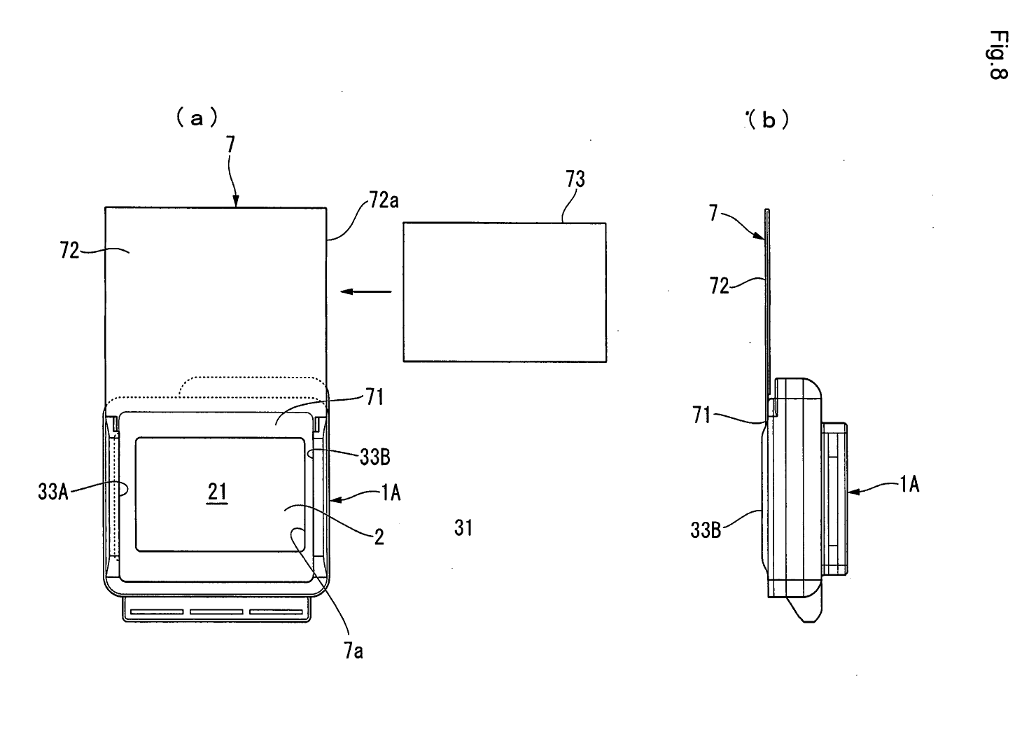

FIG. 7 is a front view illustrating structure of an electronic shelf label according to a second embodiment.

As illustrated in FIG. 7, in place of the window frame display panel 4 mounted on the display portion surface side of the electronic shelf label 1 (see FIG. 2) that is the same as that of the first embodiment, the second embodiment employs a shelf talker 6 (information display panel), which is shaped so that a display part thereof extends in a direction opposite to a direction in which the shelf talker 6 is inserted into the guide rails 33A and 33B. Specifically, the shelf talker 6 includes a frame portion 61, which is held by the guide rails 33A and 33B and has an opening portion 6a formed therein, and a projecting display portion 62, which extends upward from the frame portion 61. Note that, on both right and left sides of the frame portion 61, protruding portions (not shown) having the same shape as the protruding portions 41 (see FIG. 1) of the window frame display panel 4 according to the first embodiment are formed, and the shelf talker 6 is inserted while the protruding portions are fitted into the recessed grooves of the guide rails 33A and 33B.

In the second embodiment, the display part is increased in area by the projecting display portion 62, which extends upward from the frame portion 61, and hence there is provided an effect of displaying more information independently of the liquid crystal panel 21 of the electronic shelf label body 2.

Next, FIG. 8 are views illustrating structure of an electronic shelf label according to a third embodiment, in which FIG. 8(a) is a front view thereof and FIG. 8(b) is a side view thereof.

As illustrated in FIGS. 8(a) and 8(b), in place of the window frame display panel 4 (see FIG. 2) according to the first embodiment, the third embodiment employs a transparent clear case 7 (information display panel), into which another display member 73 can be inserted. Further, an electronic shelf label 1A of the third embodiment has a linear dimension smaller in the lateral direction than the electronic shelf label 1 (see FIG. 2) of the first embodiment. Specifically, the clear case 7 includes a frame portion 71, which is held by the guide rails 33A and 33B and has an opening portion 7a formed therein, and an insertion portion 72, which extends upward from the frame portion 71. The insertion portion 72 has an insertion slot 72a, which is formed of two cases overlapping with each other for the display member 73 to be inserted in the lateral direction.

Note that, on both right and left sides of the frame portion 71, protruding portions (not shown) having the same shape as the protruding portions 41 (see FIG. 1) of the window frame display panel 4 according to the first embodiment are formed, and the clear case 7 is inserted under a state in which the protruding portions are fitted into the recessed grooves of the guide rails 33A and 33B.

In the third embodiment, under the state in which the clear case 7 is mounted on the shelf label frame 3, the display member 73 on which character information and the like are placed as appropriate is inserted in the lateral direction into the insertion region (insertion portion 72) of the clear case 7 that is held by the guide rails 33A and 33B of the shelf label frame 3, and hence it is possible to display other information than that of the liquid crystal panel 21 of the electronic shelf label body 2.

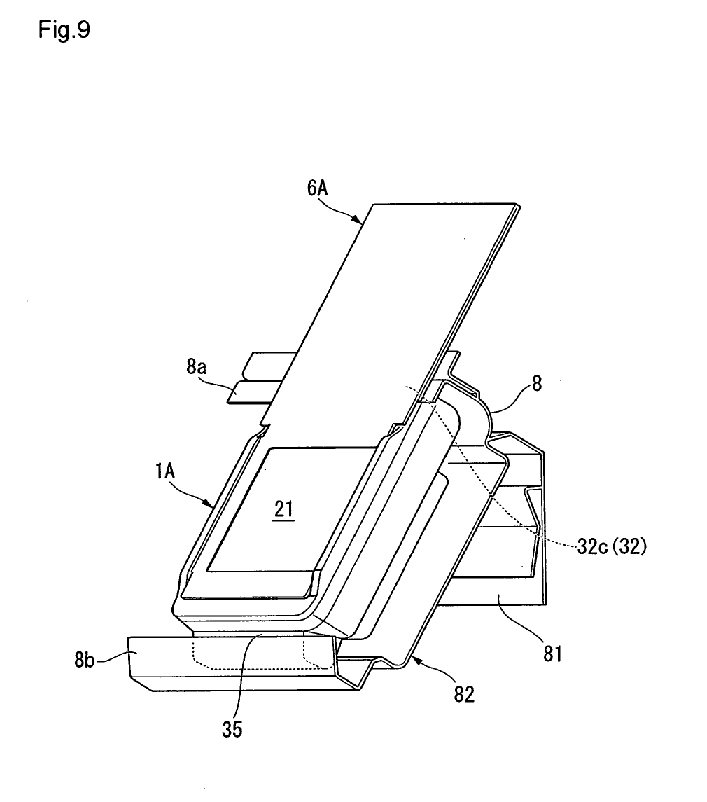

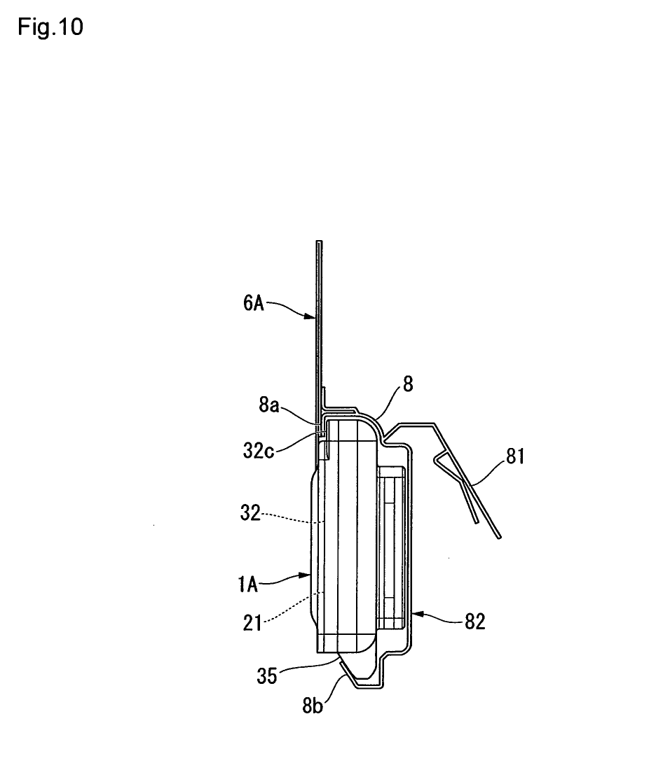

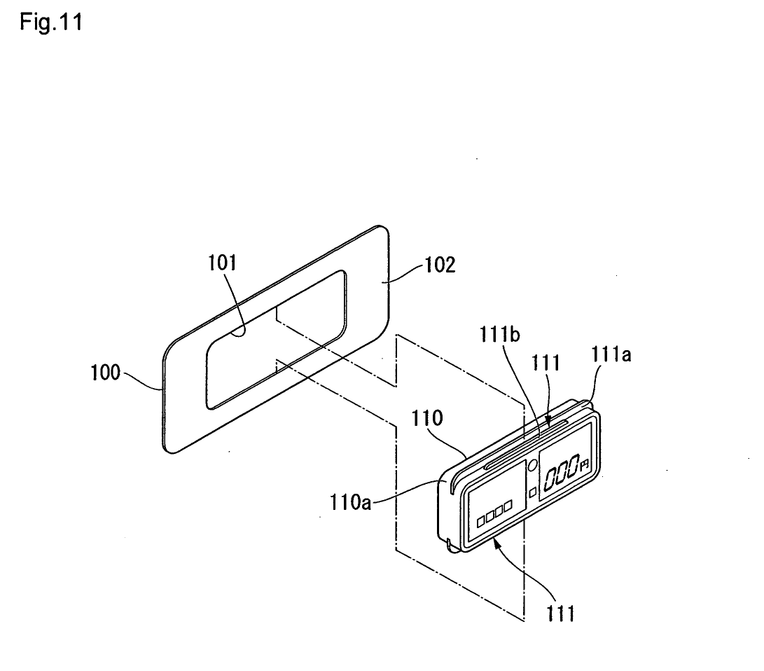

Next, FIG. 9 is a perspective view illustrating structure of an electronic shelf label according to a fourth embodiment, and illustrates a state in which the electronic shelf label is attached to a holder. FIG. 10 is a side view of the electronic shelf label illustrated in FIG. 9.

As illustrated in FIGS. 9 and 10, an electronic shelf label 1A of the fourth embodiment corresponds to the electronic shelf label 1A of the above-mentioned third embodiment, which is shorter in the lateral direction, and a shelf talker 6A, which has the same structure as that of the second embodiment and is shaped so that a lateral linear dimension thereof is adapted to that of the electronic shelf label 1A, is mounted on the electronic shelf label 1A. The electronic shelf label 1A is attached to a holder 8, which is provided to the product display shelf (not shown). In this state, the holder 8 includes an attachment portion 81 for attaching the holder 8 to part of the product shelf (not shown), and an electronic shelf label support portion 82 for supporting the electronic shelf label 1A. The electronic shelf label support portion 82 has an upper locking portion 8a and a lower locking portion 8b formed therein, the upper locking portion 8a and the lower locking portion 8b holding upper and lower portions of the electronic shelf label 1A, respectively. Specifically, the lower locking portion 8b of the holder 8 locks the barcode attachment portion 35 of the shelf label frame 3, and the upper locking portion 8a of the holder 8 locks an upper surface 32c of the frame-like portion 32.

In other words, the shelf talker 6A is located on the display surface side of the frame-like portion 32, and hence the holder 8 can be attached without interfering with the shelf talker 6A on a back surface side of the electronic shelf label 1A. Moreover, the display portion surface (liquid crystal panel 21) of the electronic shelf label 1A and the front of the holder 8 (positions of the upper locking portion 8a and the lower locking portion 8b) are substantially flush with each other, and hence the electronic shelf label 1A can be attached so as not to protrude in front of the holder 8.

Hereinabove, the description is given of the electronic shelf label, the information display panel, and the information display method according to the embodiments of the present invention, but the present invention is not limited to the above-mentioned embodiments, and appropriate modifications may be made thereto without departing from the gist of the present invention.

For example, in the embodiments herein, the guide rails 33 (33A and 33B) are arranged so as to extend in the longitudinal direction along both the edge portions 32b and 32b, which are located on both the right and left sides of the frame-like portion 32, and the information display panel is mounted by inserting the information display panel downward from above the guide rails 33. However, the present invention is not limited to such embodiments, and the guide rails may be arranged so as to extend in a lateral direction along both edge portions located at both upper and lower ends of the frame-like portion 32, and the information display panel may be mounted at a predetermined position of the frame-like portion 32 by moving the information display panel in the lateral direction. Note that, even in the case of inserting the information display panel laterally, it is preferred that a locking portion be provided so as to stop the lateral movement at a predetermined position.

Further, in the first embodiment, the bottom surface portions 41a of the protruding portions 41 of the window frame display panel 4 abut against the locking portions 33c of the guide rails 33, to thereby regulate the downward movement. However, the present invention is not limited thereto, and the frame-like portion 32 may be provided with a groove portion for supporting a lower end portion of the window frame display panel 4 from below.

Further, the specific dimensions, sizes, shapes, and the like of the opening window 32a of the frame-like portion 32, the guide rails 6, and the like may be set as appropriate depending on conditions such as the outer shape of the electronic shelf label body 2 and the size of the liquid crystal panel 21.

Further, information may be displayed on the back surface of the window frame display panel 4, and both the front and back sides of the window frame display panel 4 may be set available for information display.

### INDUSTRIAL APPLICABILITY

The present invention is applicable to an electronic shelf label and an information display panel, which are used for displaying a product price and the like in a retail store and the like.

### REFERENCE SIGNS LIST

1, 1A electronic shelf label
2 electronic shelf label body
3 shelf label frame
4 window frame display panel (information display panel)
6, 6A shelf talker (information display panel)
7 clear case (information display panel)
21 liquid crystal panel (electronic display portion)
32 frame-like portion
32a opening window (window)
33, 33A, 33B guide rail
33a recessed groove
33b insertion portion
33c locking portion
73 display member (another display member)

1. An electronic shelf label, comprising:
an electronic shelf label body including an electronic display portion; and
a shelf label frame for housing the electronic shelf label body,
wherein the shelf label frame comprises:
a frame-like portion having a window for the electronic display portion formed therein; and
a pair of opposing guide rails, which are arranged on a display portion surface side of the frame-like portion and are capable of holding an information display panel capable of displaying arbitrary information with the information display panel inserted into the pair of opposing guide rails in any one of a longitudinal direction and a lateral direction.

2. An electronic shelf label according to claim 1, wherein the information display panel can be inserted into the pair of opposing guide rails from above the display portion surface.

3.-7. (canceled)

8. An information display method, in which an electronic shelf label is used,
the electronic shelf label comprising:
an electronic shelf label body including an electronic display portion; and
a shelf label frame for housing the electronic shelf label body,
the information display method comprising:
displaying an arbitrary price on the electronic display portion of the electronic shelf label body; and
holding an information display panel with the information display panel inserted into guide rails in any one of a longitudinal direction and a lateral direction, the guide rails being provided on a display portion surface side of a frame-like portion having a window for the electronic display portion formed therein, and displaying arbitrary information on the information display panel.
